(19) United States
(12) Patent Application Publication
(10) Pub. No.: US 2026/0140143 A1
(43) Pub. Date: May 21, 2026

(54) SEMICONDUCTOR TEST APPARATUS AND SEMICONDUCTOR TEST METHOD USING THE SAME

(71) Applicant: SAMSUNG ELECTRONICS CO., LTD., Suwon-si (KR)

(72) Inventors: Chunghyun KIM, Suwon-si (KR); Won Hee KIM, Seongnam-si (KR); Chang Suk OH, Seongnam-si (KR); Kwang Hwa LEE, Seongnam-si (KR); Myoungsuk JANG, Suwon-si (KR); Dong Je JEON, Seongnam-si (KR); Seok Jae HONG, Seongnam-si (KR)

(73) Assignees: SAMSUNG ELECTRONICS CO., LTD., Suwon-si (KR); YC Corporation, Seongnam-si (KR)

(21) Appl. No.: 19/228,222

(22) Filed: Jun. 4, 2025

(30) Foreign Application Priority Data
Nov. 20, 2024 (KR) 10-2024-0166589

(51) Int. Cl. G01R 1/073

(52) U.S. Cl. CPC G01R 1/07364; G01R 1/07342

(57) ABSTRACT

A semiconductor test apparatus includes a chuck supporting a substrate, an optical device coupled with a side of the chuck, a position control processor on the chuck, a probe card between the chuck and the position control processor, and a connection part coupling the position control processor with the probe card. The connection part is configured to compensate warpage of the probe card.

### CROSS-REFERENCE TO RELATED APPLICATIONS

This application claims benefit of priority under 35 U.S.C § 119 to Korean Patent Application No. 10-2024-0166589, filed on Nov. 20, 2024, in the Korean Intellectual Property Office, the disclosure of which is incorporated by reference herein in its entirety.

### BACKGROUND

### 1. Field

The present disclosure relates generally to a semiconductor test apparatuses, and more particularly, to a semiconductor test apparatus including an optical device coupled with a side of a chuck, and a semiconductor test method using the same.

### 2. Description of Related Art

A semiconductor device may be fabricated through various processes. For example, the semiconductor device may be manufactured through one or more of a photolithography process, an etching process, a deposition process, a plating process, or the like. An electrical performance test may need to be performed on the manufacturing semiconductor device to determine whether the semiconductor device operates properly. For example, a probe card may be used to test the semiconductor device. The probe card may include one or more tips. The probe tip may contact a pad of a wafer and/or a semiconductor chip to test the electrical performance of the semiconductor device.

### SUMMARY

One or more example embodiments of the present disclosure provide a semiconductor test apparatus with reduced effects due to temperature changes, when compared to semiconductor test apparatuses, and a semiconductor test method using the same.

Further, one or more example embodiments of the present disclosure provide a semiconductor test apparatus with improved test performance, when compared to semiconductor test apparatuses, and a semiconductor test method using the same.

According to an aspect of the present disclosure, a semiconductor test apparatus includes a chuck supporting a substrate, an optical device coupled with a side of the chuck, a position control processor on the chuck, a probe card between the chuck and the position control processor, and a connection part coupling the position control processor with the probe card. The connection part is configured to compensate warpage of the probe card.

According to an aspect of the present disclosure, a semiconductor test method includes preparing a substrate in a semiconductor test apparatus, measuring a warpage of a probe card, compensating the warpage of the probe card, and detecting, using the probe card, an electrical signal of a semiconductor device included in the substrate.

According to an aspect of the present disclosure, a semiconductor test apparatus includes a prober and a tester coupled with the prober. The prober includes a chuck supporting a substrate, an optical device coupled with a side of the chuck, a position control processor on the chuck, a probe card between the chuck and the position control processor, a central coupling member coupling the position control processor with a central region of the probe card, and a plurality of auxiliary coupling members coupling the position control processor to an edge region of the probe card. The central coupling member includes a driving part configured to move in a vertical direction. The plurality of auxiliary coupling members are configured to fix the probe card.

Additional aspects may be set forth in part in the description which follows and, in part, may be apparent from the description, and/or may be learned by practice of the presented embodiments.

### BRIEF DESCRIPTION OF DRAWINGS

The above and other aspects, features, and advantages of certain embodiments of the present disclosure may be more apparent from the following description taken in conjunction with the accompanying drawings, in which:

FIG. 1 illustrates a schematic diagram showing a semiconductor test apparatus, according to some embodiments of the present disclosure;

FIG. 2 illustrates a bottom view partially showing a semiconductor test apparatus, according to some embodiments of the present disclosure;

FIG. 3 illustrates a plan view partially showing a semiconductor test apparatus, according to some embodiments of the present disclosure;

FIG. 4 illustrates a schematic diagram showing a semiconductor test apparatus, according to some embodiments of the present disclosure;

FIG. 5 illustrates a plan view partially showing a semiconductor test apparatus, according to some embodiments of the present disclosure;

FIG. 6 illustrates a flow chart showing a semiconductor test method, according to some embodiments of the present disclosure; and

FIGS. 7 to 11 illustrate cross-sectional views showing a semiconductor test method, according to some embodiments of the present disclosure.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, when an element or layer is referred to as “covering”, “overlapping”, or “surrounding” another element or layer, the element or layer may cover at least a portion of the other element or layer, where the portion may include a fraction of the other element or may include an entirety of the other element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

It is to be understood that the specific order or hierarchy of blocks in the processes/flowcharts disclosed are an illustration of exemplary approaches. Based upon design preferences, it is understood that the specific order or hierarchy of blocks in the processes/flowcharts may be rearranged. Further, some blocks may be combined or omitted. The accompanying claims present elements of the various blocks in a sample order, and are not meant to be limited to the specific order or hierarchy presented.

The embodiments herein may be described and illustrated in terms of blocks, as shown in the drawings, which carry out a described function or functions. These blocks, which may be referred to herein as units or modules or the like, or by names such as device, logic, circuit, controller, counter, comparator, generator, converter, or the like, may be physically implemented by analog and/or digital circuits including one or more of a logic gate, an integrated circuit, a microprocessor, a microcontroller, a memory circuit, a passive electronic component, an active electronic component, an optical component, and the like.

In the present disclosure, the articles “a” and “an” are intended to include one or more items, and may be used interchangeably with “one or more.” Where only one item is intended, the term “one” or similar language is used. For example, the term “a processor” may refer to either a single processor or multiple processors. When a processor is described as carrying out an operation and the processor is referred to perform an additional operation, the multiple operations may be executed by either a single processor or any one or a combination of multiple processors.

Hereinafter, various embodiments of the present disclosure are described with reference to the accompanying drawings.

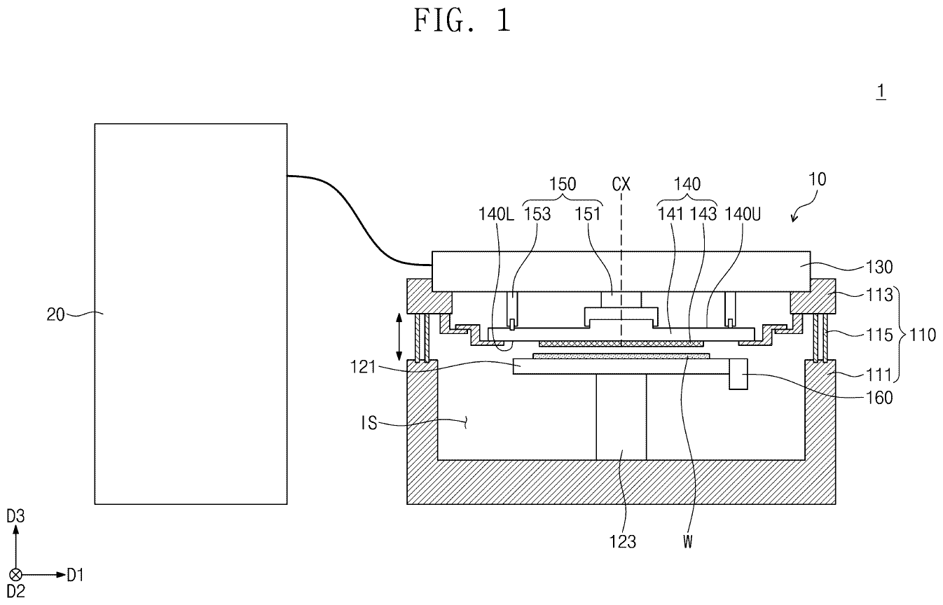

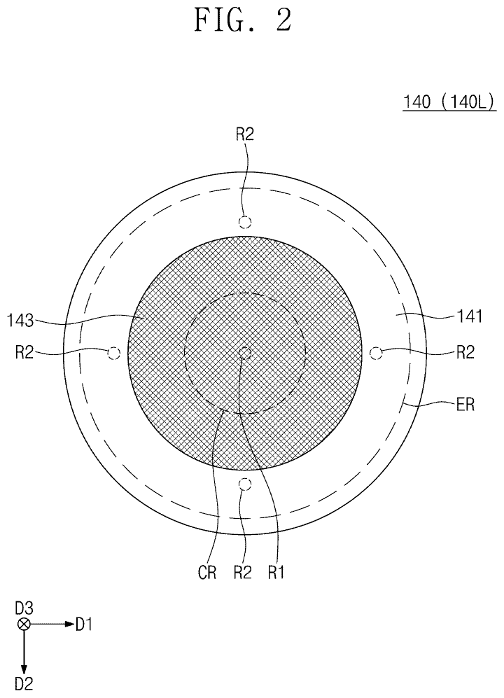

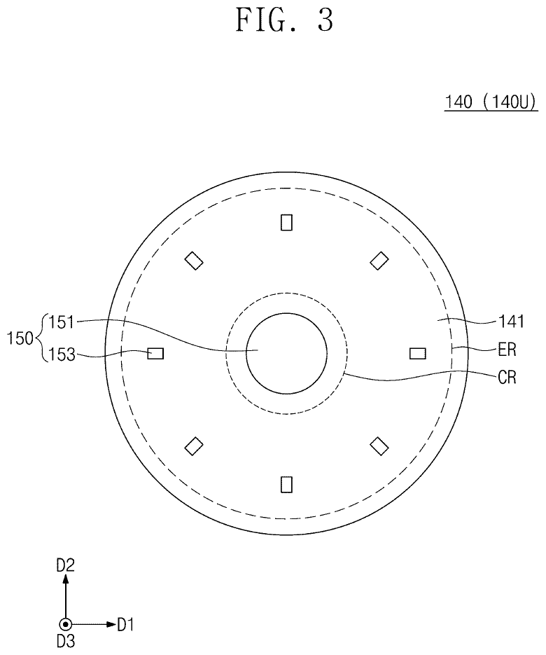

FIG. 1 illustrates a schematic diagram showing a semiconductor test apparatus, according to some embodiments of the present disclosure. FIG. 2 illustrates a bottom view partially showing a semiconductor test apparatus, according to some embodiments of the present disclosure. FIG. 3 illustrates a plan view partially showing a semiconductor test apparatus, according to some embodiments of the present disclosure.

Referring to FIGS. 1, 2, and 3, a semiconductor test apparatus 1 may be provided. The semiconductor test apparatus 1 may be an apparatus for inspecting whether a semiconductor device operates or not. As used herein, a semiconductor device may refer to a memory device such as, but not limited to, dynamic random-access memory (DRAM), NAND memory, flash memory, static random-access memory (SRAM), or the like, and/or a logic device such as, but not limited to, a central processing unit (CPU), a graphics processing unit (GPU), a field programmable gate array (FPGA), an application-specific integrated circuit ASIC, or the like. However, embodiments of the present disclosure are not limited in this regard. For example, the semiconductor test apparatus 1 may include an electrical die sorting (EDS) test apparatus.

The semiconductor test apparatus 1 may include a prober 10 and a tester 20 that may be electrically connected to the prober 10 and configured to transceive electrical signals with the prober 10. For example, the prober 10 may include a chamber 110, a chuck 121, a position control processor 130, a probe card 140, a connection part 150, and an optical device 160.

The chamber 110 may provide a space where a semiconductor device may be inspected. For example, the chamber 110 may include a lower housing 111, an upper housing 113 on the lower housing 111, and a position controller 115 between the lower housing 111 and the upper housing 113. The lower housing 111 may provide an inner space IS that may accommodate the chuck 121 and a stage 123. The lower housing 111 may include a heater therein. During operations to inspect semiconductor devices, heat may be provided by the heater of the lower housing 111 to maintain the inner space IS of the lower housing 111 at relatively high temperatures. For example, the inner space IS of the lower housing 111 may be maintained at about 100° C. to about 150° C. Consequently, warpage of the probe card 140 may occur due to relatively high temperatures.

The upper housing 113 may rigidly place the position control processor 130 and the probe card 140. The position controller 115 may drive the upper housing 113 to move in a first direction D1 and a second direction D2. In addition, the position controller 115 may drive the upper housing 113 to move in a third direction D3 from the lower housing 111.

In some embodiments of the present disclosure, the first direction D1 and the second direction D2 may intersect each other. The third direction D3 may intersect the first direction D1 and the second direction D2. For example, the first direction D1, the second direction D2, and the third direction D3 may be orthogonal to each other. As used herein, the first direction D1 and the second direction D2 may be referred to as a horizontal direction, and/or the third direction D3 may be referred to as a vertical direction.

The chuck 121 may be positioned inside the lower housing 111. A substrate W including semiconductor devices may be placed on the chuck 121. The chuck 121 may support and hold the substrate W at a certain location (e.g., position and/or orientation). For example, the chuck 121 may use an electrostatic force and/or a vacuum force to fix the substrate W. As used herein, a substrate may refer to a silicon (Si) wafer. However, embodiments of the present disclosure are not limited thereto.

A stage 123 may be provided between the chuck 121 and the lower housing 111. The stage 123 may be positioned on a floor of the lower housing 111, and may combine (couple) the lower housing 111 and the chuck 121 with each other. The stage 123 may be configured to move in the first direction D1 and the second direction D2. In addition, the stage 123 may be configured to move in the third direction D3. For example, the stage 123 may be configured to move in a horizontal direction and a vertical direction. Thus, the chuck 121 combined with the stage 123 may also move in a horizontal direction and a vertical direction.

The position control processor 130 may be located on the chuck 121 and the substrate W. The position control processor 130 may be combined with the chuck 121 and separated from the upper housing 113. The position control processor 130 may control a position of the substrate W to align the probe card 140 and the substrate W. Additionally and/or alternatively, the position control processor 130 may detect electrical signals through the probe card 140 from semiconductor devices of the substrate W, and may transfer the electrical signals to the tester 20. For example, the position control processor 130 may include, for example, a wafer mapping board (WMB) frame.

In some embodiments of the present disclosure, the position control processor 130 may be physically implemented by and/or may include analog and/or digital circuits including one or more of a logic gate, an integrated circuit, a microprocessor, a microcontroller, a memory circuit, a passive electronic component, an active electronic component, an optical component, and the like. For example, an FPGA may be used to implement custom logic that may include the functionality of the position control processor 130. As another example, a processor in combination with a memory may be used to execute one or more instructions to perform the functionality of the position control processor 130. Alternatively or additionally, at least a portion of the functionality of position control processor 130 may be incorporated into an external processor and/or implemented as instructions to be executed by the external processor.

The probe card 140 may be placed between the chuck 121 and the position control processor 130. The probe card 140 may be disposed to vertically overlap the chuck 121 and the substrate W. The probe card 140 may be in partial contact with the upper housing 113. The probe card 140 may be connected to the position control processor 130 through the connection part 150. The probe card 140 may have a central axis CX that may be parallel to the third direction D3. The probe card 140 may have a disk shape centered on the central axis CX.

The probe card 140 may have a bottom surface 140L and a top surface 140U opposite to the bottom surface 140L. The bottom surface 140L of the probe card 140 may be directed toward the chuck 121 and the substrate W. The top surface 140U of the probe card 140 may be directed toward the position control processor 130. In addition, the probe card 140 may include a central region CR and an edge region ER. When viewed in a plan view, the edge region ER may surround the central region CR. The central region CR may be and/or may include an area that may be adjacent to the central axis CX of the probe card 140. The edge region ER may be and/or may include an area spaced apart from the central axis CX of the probe card 140, and may have a ring shape.

According to some embodiments, the probe card 140 may include a probe substrate 141 and a pin structure 143 below the probe substrate 141. The probe substrate 141 may fix the pin structure 143. The probe substrate 141 may be mounted thereon with electronic devices such as, but not limited to, microprocessors, memories, transistors, capacitors, resistors, diodes, and/or wiring lines that may control detection signals of the pin structure 143. For example, the probe substrate 141 may include a printed circuit board (PCB). The pin structure 143 may be electrically connected to the probe substrate 141. For example, the pin structure 143 may include a plurality of needles in contact with the semiconductor devices.

The connection part 150 may reside between and connect to each of the position control processor 130 and the probe card 140. For example, the connection part 150 may rigidly place the probe card 140 on a certain location. The connection part 150 may include a central coupling member 151 and an auxiliary coupling member 153. In addition, the auxiliary coupling member 153 may be provided in plural. That is, the auxiliary coupling member 153 may be and/or may include a plurality of auxiliary coupling members.

The central coupling member 151 of the connection part 150 may have a shape that may extend in the third direction D3 between the position control processor 130 and the probe card 140. The central coupling member 151 may be combined (coupled) with the central region CR of the probe card 140. For example, the central coupling member 151 may overlap the central axis CX of the probe card 140. According to some embodiments, the central coupling member 151 may include a clamp that may fix the probe card 140 and a driving part that may move in the third direction D3. As such, the central region CR of the probe card 140 may move in the third direction D3 along the central coupling member 151.

The auxiliary coupling member 153 of the connection part 150 may have a shape that may extend in the third direction D3 between the position control processor 130 and the probe card 140. The auxiliary coupling member 153 may be positioned next to and spaced apart from the central coupling member 151. The auxiliary coupling member 153 may be combined with the edge region ER of the probe card 140. Additionally, the auxiliary coupling member 153 may be spaced apart from the central axis CX of the probe card 140. For example, the auxiliary coupling member 153 may be and/or may include a pneumatic and/or hydraulic cylinder having a fixed length. Consequently, the edge region ER of the probe card 140 may have a fixed height and may not move in the third direction D3. Unlike the central coupling member 151, the auxiliary coupling member 153 may be configured to fix the probe card 140.

When the auxiliary coupling member 153 is provided in plural, the plurality of auxiliary coupling members 153 may be spaced apart from each other and combined (coupled) with the probe card 140. The plurality of auxiliary coupling members 153 may be arranged along a circumferential direction around the central axis CX of the probe card 140.

The optical device 160 may be connected to and disposed on one side of the chuck 121. In addition, the optical device 160 may be aligned with a top surface of the chuck 121. The optical device 160 may measure warpage of the probe card 140. For example, the optical device 160 may include a vision camera.

For example, the optical device 160 may measure levels of a bottom surface 140L of the probe card 140 on a plurality of sections of the bottom surface 140L of the probe card 140. As used herein, a level may refer to a height in the third direction D3 from the optical device 160 or the top surface of the chuck 121. The plurality of sections of the bottom surface 140L of the probe card 140 may include a first region R1 and second regions R2. The first region R1 may be located in the central region CR of the probe card 140. For example, the first region R1 may overlap the central axis CX of the probe card 140. The second regions R2 may be located in the edge region ER of the probe card 140. The second regions R2 may be equally spaced apart from each other. For example, the second regions R2 may be spaced apart from each other in the first direction D1 and the second direction D2 around the first region R1.

The optical device 160 combined with the chuck 121 may move, together with the stage 123, in the first direction D1 and the second direction D2. The optical device 160 may measure levels of the bottom surface 140L of the probe card 140, while moving in the first direction D1 and the second direction D2. The tester 20 may receive information about the levels of the bottom surface 140L of the probe card 140, for example, the levels may be measured on the first region R1 and the second regions R2.

The tester 20 may be electrically connected to the prober 10 and receive electrical signals from the prober 10. The tester 20 may analyze various electrical signals such as, but not limited to, resistance, voltage, and current of semiconductor devices detected through the probe card 140. Thus, the tester 20 may inspect whether semiconductor devices operate normally or not. For example, the tester 20 may determine (or identify) defective devices from among the semiconductor devices.

Additionally, the tester 20 may analyze information of the levels of the bottom surface 140L of the probe card 140, which may be obtained from the optical device 160. When the levels of the bottom surface 140L of the probe card 140 are different between the first region R1 and the second regions R2 (e.g., a difference in level may be equal to or greater than about 30 micrometers (μm), the tester 20 may cause the central coupling member 151 to ascend and/or descend in the third direction D3. As the central coupling member 151 moves in the third direction D3, the central region CR of the probe card 140 may be pushed and/or pulled in the third direction D3. Therefore, it may be possible to compensate for temperature-induced warpage of the probe card 140. Accordingly, the levels of the bottom surface 140L of the probe card 140 may become substantially similar and/or the same between the first region R1 and the second regions R2.

The semiconductor test apparatus 1, according to some embodiments of the present disclosure, may be configured such that the optical device 160 may be used to measure the level of the bottom surface 140L of the probe card 140, and the central coupling member 151 of the connection part 150 may be used to compensate temperature-induced warpage of the probe card 140.

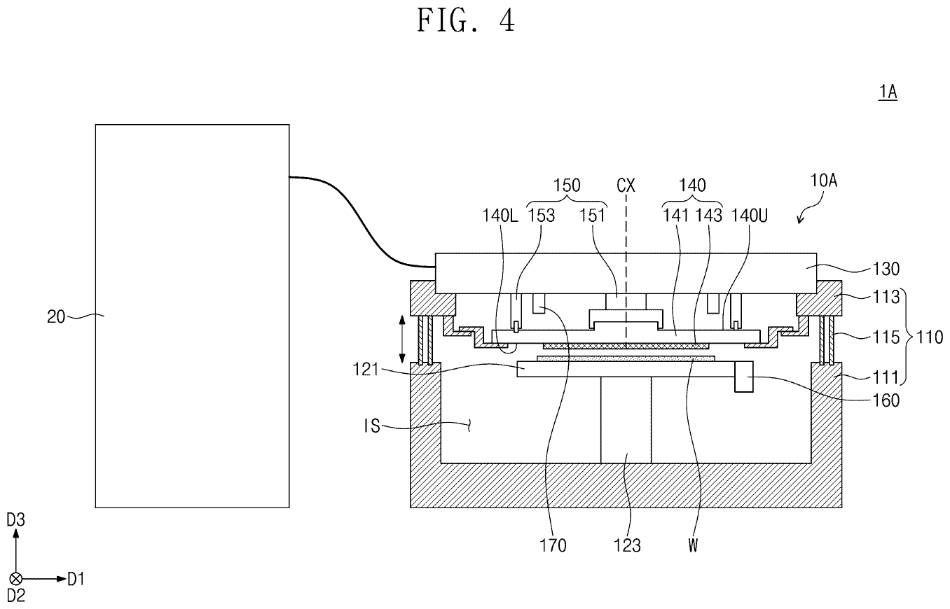

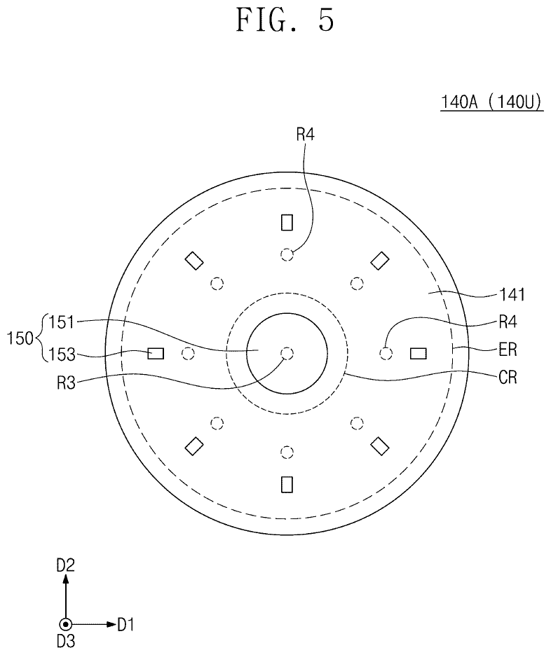

FIG. 4 illustrates a schematic diagram showing a semiconductor test apparatus, according to some embodiments of the present disclosure. FIG. 5 illustrates a plan view partially showing a semiconductor test apparatus, according to some embodiments of the present disclosure.

Referring to FIGS. 4 and 5, the semiconductor test apparatus 1A of FIGS. 4 and 5 may include and/or may be similar in many respects to the semiconductor test apparatus 1 described above with reference to FIGS. 1 to 3, and may include additional features not mentioned above. Furthermore, the prober 10A and the probe card 140A may include and/or may be similar in many respects to the prober 10 and the probe card 140, respectively, described above with reference to FIGS. 1 to 3, and may include additional features not mentioned above. Consequently, repeated descriptions of the semiconductor test apparatus 1A described above with reference to FIGS. 1 to 3 may be omitted for the sake of brevity.

For example, the semiconductor test apparatus 1A may further include upper optical devices 170. The upper optical devices 170 may be combined with a lower portion of the position control processor 130. The upper optical device 170 may measure warpage of the probe card 140A. The upper optical devices 170 may include a vision camera. However, embodiments of the present disclosure are not limited thereto.

In some embodiments of the present disclosure, the upper optical devices 170 may measure levels of a top surface 140U of the probe card 140A on a plurality of sections of the top surface 140U of the probe card 140A. The plurality of sections of the top surface 140U of the probe card 140A may include a third region R3 and fourth regions R4. The third region R3 may be located in the central region CR of the probe card 140. For example, the third region R3 may overlap the central axis CX of the probe card 140A and the first region R1 on the bottom surface 140L. The fourth regions R4 may be located in the edge region ER of the probe card 140A. The fourth regions R4 may be equally spaced apart from each other. For example, the fourth regions R4 may be arranged in a circumferential direction around the central axis CX of the probe card 140A. The fourth regions R4 may be correspondingly adjacent to the auxiliary coupling members 153. However, embodiments of the present disclosure are not limited thereto.

In some embodiments, one of the upper optical devices 170 may be located in the central coupling member 151 to measure a level of the top surface 140U of the probe card 140A on the third region R3. Others of the upper optical devices 170 may measure levels of the top surface 140U of the probe card 140A on the fourth regions R4. The tester 20 may receive information of the levels of the top surface 140U of the probe card 140A. The tester 20 may collect information of the levels, obtained from the optical device 160, of the bottom surface 140L of the probe card 140A and information of the levels, obtained from the upper optical devices 170, of the top surface 140U of the probe card 140, thereby compensating warpage of the probe card 140A.

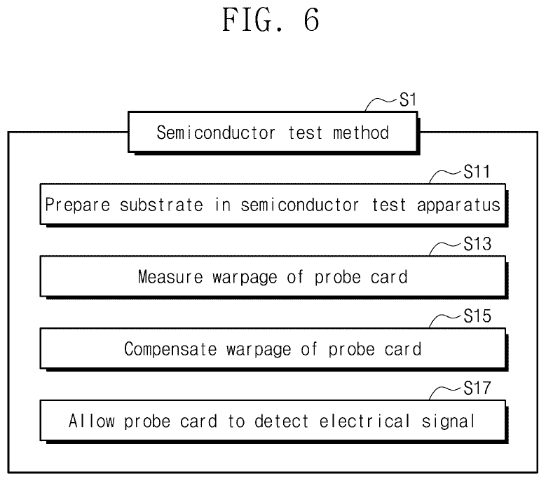

FIG. 6 illustrates a flow chart showing a semiconductor test method, according to some embodiments of the present disclosure.

Referring to FIG. 6, a semiconductor test method S1 may be provided. The semiconductor test method S1 may be a method of inspecting a semiconductor device by using the semiconductor test apparatuses 1 and 1A described with reference to FIGS. 1 to 5. The semiconductor test method S1 may include preparing a substrate in a semiconductor test apparatus (operation S11), measuring warpage of a probe card (operation S13), compensating the warpage of the probe card (operation S15), and allowing the probe card to detect an electrical signal (operation S17).

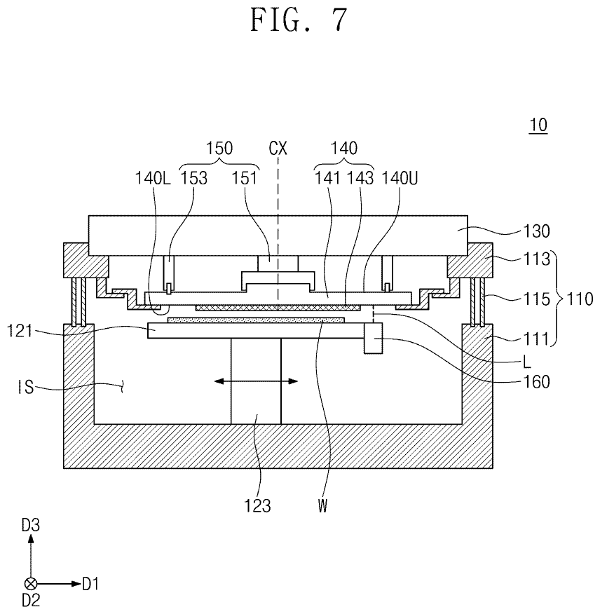

Hereinafter, the semiconductor test method S1 of FIG. 6 are described with reference to FIGS. 7 to 11.

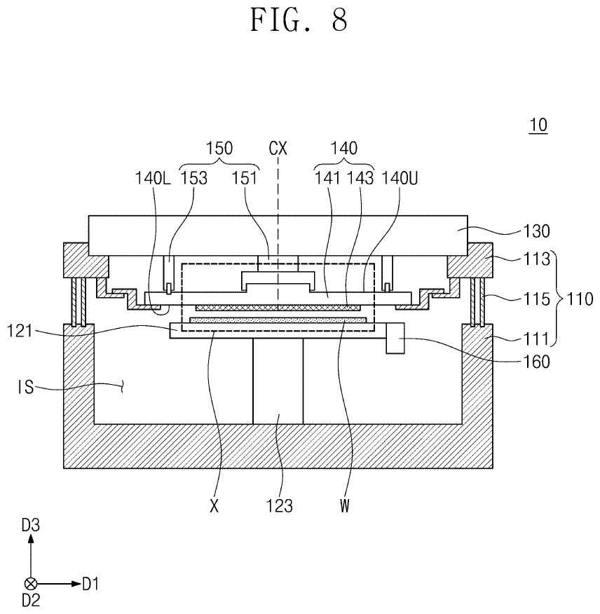

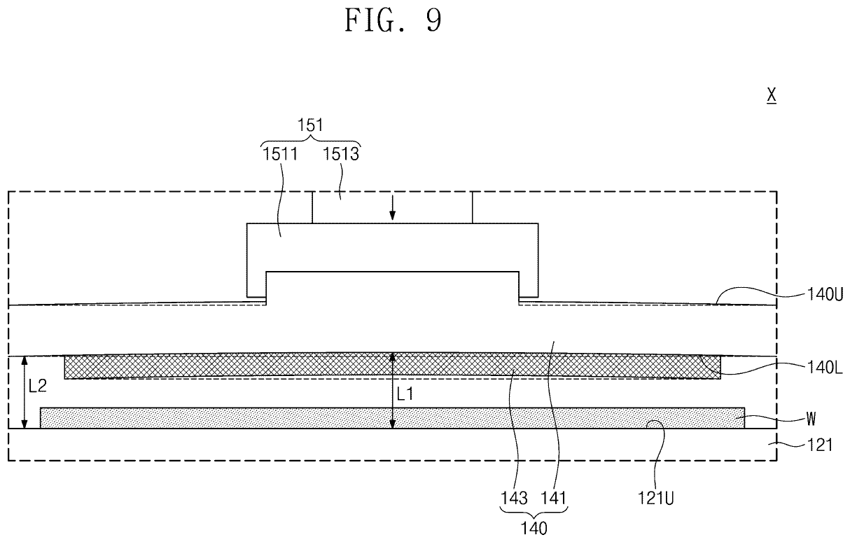

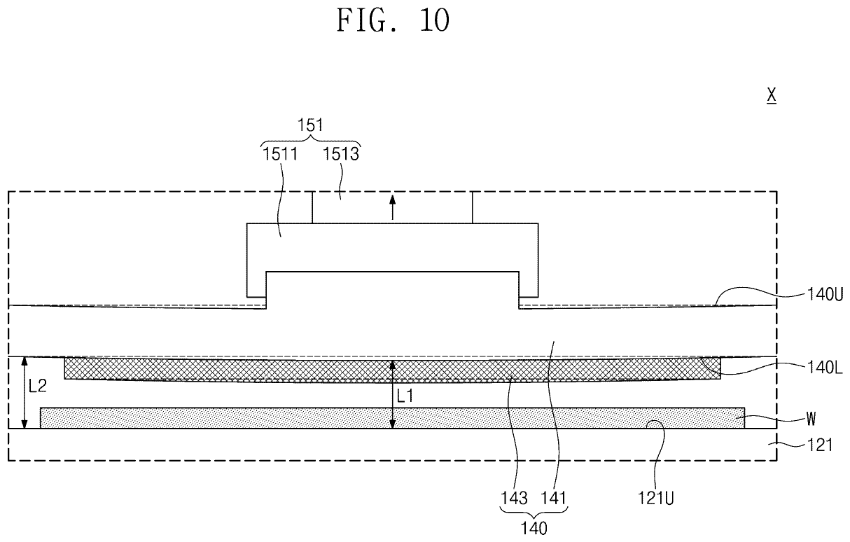

FIGS. 7 to 11 illustrate cross-sectional views showing a semiconductor test method, according to some embodiments of the present disclosure. FIGS. 7, 8, and 11 are views showing a semiconductor test method. FIGS. 9 and 10 are enlarged views showing section X depicted in FIG. 8.

Referring to FIGS. 6 and 7, the substrate preparation operation S11 may include placing the substrate W on the chuck 121. The substrate W may include integrated semiconductor devices. The substrate W may be disposed on the chuck 121 such that a top surface of the substrate W is parallel to the first direction D1 and the second direction D2 and perpendicular to the third direction D3. The substrate W disposed on the chuck 121 may be held by the chuck 121. For example, the chuck 121 may use an electrostatic force and/or a vacuum force to hold the substrate W.

The substrate preparation operation S11 may further include maintaining the inner space IS of the lower housing 111 at relatively high temperatures. The high temperature operation may be performed by a heater of the lower housing 111. For example, the inner space IS of the lower housing 111 may be heated between about 100° C. and about 150° C. Therefore, the probe card 140 may suffer from warpage due to relatively high temperatures.

The warpage measurement operation S13 may include allowing the stage 123 to move in a horizontal direction. For example, the stage 123 and the chuck 121 connected to the stage 123 may move in the first direction D1 and the second direction D2 in the lower housing 111. The optical device 160 that may be combined (coupled) with the chuck 121 may also move in the first direction D1 and the second direction D2. Thus, the optical device 160 may vertically overlap the first region R1 and the second regions R2 on the bottom surface 140L of the probe card 140 as described with reference to FIG. 2.

In addition, the warpage measurement operation S13 may include measuring a level of the bottom surface 140L of the probe card 140. The level measurement operation may be performed by the optical device 160 combined with one side of the chuck 121. The optical device 160 may irradiate an optical signal L, such as, but not limited to, a laser, toward the bottom surface 140L of the probe card 140, thereby measuring a level of the bottom surface 140L of the probe card 140.

Referring together to FIG. 2, the optical device 160 may vertically overlap the first region R1 and the second regions R2, while moving in the first direction D1 and the second direction D2. In this stage, the optical device 160 may use the optical signal L to measure levels of the bottom surface 140L of the probe card 140 on the first region R1 and the second regions R2. For example, the level measurement operation may include measuring levels of a plurality of sections on the bottom surface 140L of the probe card 140.

According to some embodiments, in the warpage measurement operation S13, the horizontal movement of the chuck 121 may be performed substantially simultaneously (e.g., at a substantially same time) with the level measurement of the bottom surface 140L of the probe card 140.

According to some embodiments, the warpage measurement operation S13 may further include measuring a level of the top surface 140U of the probe card 140. The upper optical devices 170 described with reference to FIG. 4 may measure levels of the top surfaces 140U of the probe card 140. In this case, warpage of the probe card 140 may be detected through the level of the top surface 140U of the probe card 140 and the level of the bottom surface 140L of the probe card 140.

Referring to FIGS. 6 and 8 to 10, the central coupling member 151 may include a clamp 1511 and a driving part 1513. Between the probe card 140 and the driving part 1513, the clamp 1511 may fix the probe card 140 to the central coupling member 151. The driving part 1513 may be configured to move in the third direction D3 perpendicular to a top surface 121U of the chuck 121. As the driving part 1513 moves in the third direction D3, the clamp 1511 may pull the probe card 140 in the third direction D3 and/or push the probe card 140 in a direction opposite to the third direction D3.

The optical device 160 may measure a first level L1 and a second level L2 between the top surface 121U of the chuck 121 and the bottom surface 140L of the probe card 140. The first level L1 and the second level L2 may be a height or distance in the third direction D3 from the top surface 121U of the chuck 121 to the bottom surface 140L of the probe card 140. For example, the first level L1 may be a level of the bottom surface 140L of the probe card 140, which may be measured on the first region R1 of FIG. 2. The second level L2 may be a level of the bottom surface 140L of the probe card 140, which may be measured from one of the second regions R2.

According to some embodiments, the first level L1 may be greater than the second level L2. The probe card 140 may have a shape that may be concave toward the chuck 121 and the substrate W. In this case, the driving part 1513 may descend along the third direction D3. Thus, the clamp 1511 may push, in a direction opposite to the third direction D3, the central region CR of the probe card 140, as shown in FIG. 2. The driving part 1513 may descend along the third direction D3 until the first level L1 and the second level L2 may become substantially similar and/or the same as each other. For example, the warpage compensation operation S15 may include allowing the central coupling member 151 to descend in a vertical direction.

According to some embodiments, the first level L1 may be less than the second level L2. The probe card 140 may have a shape that may be convex toward the chuck 121 and the substrate W. In this case, the driving part 1513 may ascend along the third direction D3. Thus, the clamp 1511 may pull, in the third direction D3, the central region CR of the probe card 140, as shown in FIG. 2. The driving part 1513 may ascend along the third direction D3 until the first level L1 and the second level L2 may become substantially similar and/or the same as each other. For example, the warpage compensation operation S15 may include allowing the central coupling member 151 to ascend in a vertical direction.

In some embodiments, the warpage compensation operation S15 may be performed by the central coupling member 151 of the connection part 150. The warpage compensation operation S15 may include allowing the central coupling member 151 to descend and/or ascend in a vertical direction. In this case, the auxiliary coupling member 153 may fix the edge region ER of the probe card 140 as described with reference to FIGS. 2 and 3. Thus, as only the central region CR of the probe card 140 is pushed or pulled in a vertical direction, an overall uniform distance may be provided between the bottom surface 140L of the probe card 140 and the top surface 121U of the chuck 121, and/or the level of the bottom surface 140L of the probe card 140 may become uniform. As a result, the central coupling member 151 of the connection part 150 may compensate warpage of the probe card 140.

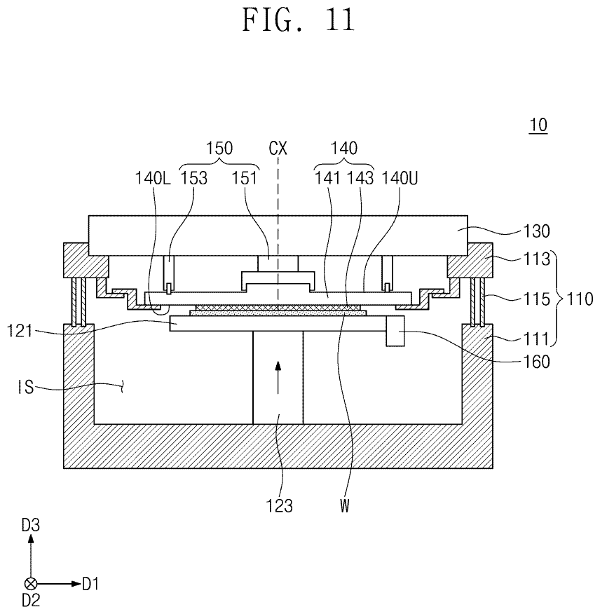

Referring to FIGS. 6 and 11, the electrical signal detection operation S17 may include allowing the pin structure 143 of the probe card 140 to contact the substrate W. The stage 123 may ascend in the third direction D3 to allow the pin structure 143 of the probe card 140 to contact the substrate W. Thus, the chuck 121 and the substrate W on the chuck 121 may move in the third direction D3. Therefore, semiconductor devices of the substrate W receive an electrical signal from the probe card 140, while being in contact with the pin structure 143.

An electrical signal with respect to electrical characteristics of semiconductor devices may be transferred through the probe card 140 to the tester 20 of FIG. 1. The tester 20 may analyze electrical signals of semiconductor devices to determine defective ones from among the semiconductor devices.

According to some embodiments, the semiconductor test method S1 may further include subsequently measuring warpage of the probe card 140 between the warpage compensation operation S15 and the electrical signal detection operation S17. For example, the subsequent measurement operation may be an operation of verifying whether the level of the bottom surface 140L of the probe card 140 becomes uniform by the warpage compensation operation S15.

The semiconductor test method S1 may include the operation S15 of compensating heat-induced warpage of the probe card 140. The warpage of the probe card 140 may be compensated to prevent contact between the substrate W and only a portion of the pin structure 143 of the probe card 140. Thus, the pin structure 143 of the probe card 140 may be in uniform contact with the substrate W. As a result, it may be possible to improve test accuracy of the semiconductor device.

A semiconductor device, according to some embodiments of the present disclosure, may be configured such that an optical device combined with a chuck is used to measure levels of a bottom surface of a probe card, and that a central coupling member of a connection part is used to compensate temperature-induced warpage of the probe card. Therefore, a pin structure of the probe card may be in uniform contact with a substrate. Consequently, a test accuracy of a semiconductor test apparatus may be improved, when compared to related semiconductor test apparatuses.

Although the present disclosure has been described in connection with the embodiments of the present disclosure illustrated in the accompanying drawings, it is to be understood to those skilled in the art that various changes and modifications may be made without departing from the technical spirit and essential feature of the present disclosure. It therefore is to be understood that the embodiments described above are just illustrative but not limitative in all aspects.

What is claimed is:

1. A semiconductor test apparatus, comprising:
a chuck supporting a substrate;
an optical device coupled with a side of the chuck;
a position control processor on the chuck;
a probe card between the chuck and the position control processor; and
a connection part coupling the position control processor with the probe card,
wherein the connection part is configured to compensate warpage of the probe card.

2. The semiconductor test apparatus of claim 1, wherein the connection part comprises:
a central coupling member; and
an auxiliary coupling member on a side of the central coupling member.

3. The semiconductor test apparatus of claim 2, wherein the central coupling member at least partially overlaps a central axis of the probe card, and
wherein the auxiliary coupling member is spaced apart from the central axis of the probe card.

4. The semiconductor test apparatus of claim 3, wherein the central coupling member comprises a driving part configured to move in a vertical direction.

5. The semiconductor test apparatus of claim 3, wherein the auxiliary coupling member is configured to fix the probe card.

6. The semiconductor test apparatus of claim 3, wherein the auxiliary coupling member comprises a plurality of auxiliary coupling members, and
wherein the plurality of auxiliary coupling members are disposed along a circumferential direction around the central axis of the probe card.

7. The semiconductor test apparatus of claim 1, wherein the chuck is configured to move in a horizontal direction, and
wherein the optical device is configured to measure a level of a bottom surface of the probe card.

8. The semiconductor test apparatus of claim 7, further comprising:
a tester coupled with the optical device and the position control processor,
wherein the tester is configured to:
analyze information of the level of the bottom surface of the probe card obtained from the optical device, and
control the connection part.

9. A semiconductor test method, comprising:
preparing a substrate in a semiconductor test apparatus;
measuring a warpage of a probe card;
compensating the warpage of the probe card; and
detecting, using the probe card, an electrical signal of a semiconductor device comprised in the substrate.

10. The semiconductor test method of claim 9, wherein the measuring of the warpage comprises:
measuring a level of a bottom surface of the probe card.

11. The semiconductor test method of claim 10, wherein the preparing of the substrate comprises placing the substrate on a chuck of the semiconductor test apparatus, and
wherein the measuring of the warpage comprises moving the chuck in a horizontal direction.

12. The semiconductor test method of claim 10, wherein the measuring of the level of the bottom surface of the probe card comprises measuring levels of a plurality of sections on the bottom surface of the probe card, and
wherein at least one section of the plurality of sections at least partially overlaps a central axis of the probe card.

13. The semiconductor test method of claim 10, wherein the measuring of the warpage further comprises measuring a level of a top surface of the probe card.

14. The semiconductor test method of claim 9, wherein the compensating of the warpage comprises compensating the warpage of the probe card using a connection part coupling a position control processor with the probe card.

15. The semiconductor test method of claim 14, wherein the connection part comprises:
a central coupling member connected to a central region of the probe card; and
an auxiliary coupling member connected to an edge region of the probe card,
wherein the auxiliary coupling member is configured to fix the edge region of the probe card.

16. The semiconductor test method of claim 15, wherein the compensating of the warpage comprises:
based on a bottom surface of the probe card being convex toward the substrate, moving a central coupling member of the connection part in an upward vertical direction.

17. The semiconductor test method of claim 15, wherein the compensating of the warpage comprises:
based on a bottom surface of the probe card being concave toward the substrate, moving a central coupling member of the connection part to in a downward vertical direction.

18. The semiconductor test method of claim 9, wherein the probe card comprises:
a probe substrate; and
a pin structure below the probe substrate,
wherein allowing the probe card to detect the electrical signal of the semiconductor device comprises allowing the pin structure to contact the substrate.

19. A semiconductor test apparatus, comprising:
a prober; and
a tester coupled with the prober,
wherein the prober comprises:
a chuck supporting a substrate;
an optical device coupled with a side of the chuck;
a position control processor on the chuck;
a probe card between the chuck and the position control processor;
a central coupling member coupling the position control processor with a central region of the probe card; and
a plurality of auxiliary coupling members coupling the position control processor to an edge region of the probe card,
wherein the central coupling member comprises a driving part configured to move in a vertical direction, and
wherein the plurality of auxiliary coupling members are configured to fix the probe card.

20. The semiconductor test apparatus of claim 19, wherein the optical device is configured to measure warpage of the probe card, and
wherein the tester is configured to control the central coupling member to compensate the warpage of the probe card.
